(19) United States
(12) Patent Application Publication
(10) Pub. No.: US 2011/0272002 A1
(43) Pub. Date: Nov. 10, 2011

(54) SUNLIGHT COLLECTING SYSTEM FOR ILLUMINATION

(76) Inventor: KEH-SHIUM LIU, Zhudong Township (TW)

(21) Appl. No.: 13/100,269

(22) Filed: May 3, 2011

(30) Foreign Application Priority Data
May 5, 2010 (TW) 099114425
Aug. 18, 2010 (TW) 099215905

(51) Int. Cl. H01L 31/052; G02B 5/20; G02B 5/26; G02B 17/00

(52) U.S. Cl. 136/246; 359/597; 359/361; 359/350

(57) ABSTRACT

A sunlight collecting system generally comprises a light receiving module, a first light directing pipe, a second light directing pipe, and a third light directing pipe. The light receiving module includes a primary reflector and a secondary reflector. The primary reflector is structured in a way that an array of reflecting units can condense and direct sunlight to the secondary reflector, which in turn directs the sunlight sequentially into the first, second and third light directing pipes and finally to a residence house or office building for illumination, landscape gardening, decoration, temperature adjustment, power generation, energy storage, and so on. The installation of the system allows the light receiving module to rotate horizontally or vertically around an axis to an orientation best suitable for collecting the sunlight. The system is easy to install and it collects and directs sunlight efficiently.

### TECHNICAL FIELD OF THE INVENTION

The present invention relates to a sunlight collecting system for illumination and, more specifically, to a system that can collect sunlight and direct the light beam to a residence house or an office building to provide illumination.

### DESCRIPTION OF THE PRIOR ART

A courtyard or interior of a building, cultivated with flowers and plants or installed with ecological ponds, is usually covered with a transparent ceiling or glass to enable sunlight to penetrate into the courtyard of the building. Because of the imperfect transparency of the ceiling or glass, the sunlight entering the courtyard of the building is often not sufficient for an application, such as gardening or decoration; therefore, additional electrical lamps are required. Thus, there is a need for implementing a device that can collect and direct sunlight efficiently to provide adequate illumination to save power.

Presently for conventional sunlight collecting devices, two patents, the U.S. Pat. No. 6,128,905, and the U.S. Pat. No. 6,691,701, have been disclosed, in which a primary reflector is employed to work with a secondary reflector to redirect sunlight to the courtyard of a building. According to these two patents, since the sunlight is directed via a number of reflectors without using a light pipe, it is difficult for the disclosed device to direct the sunlight efficiently for all applications. Also, the disclosed device has a possibility of being interfered by air dust and thus causing additional sunlight loss.

To overcome the drawbacks, the present invention proposes a sunlight collecting system that directs sunlight with reflective pipes in addition to reflectors to improve the collecting effect of sunlight.

### SUMMARY OF THE INVENTION

The primary object of the present invention is to provide a sunlight collecting system that can collect and direct sunlight more efficiently for illumination.

One feature of the present invention is that, the sunlight collecting system comprises a light receiving module, a first light directing pipe, a second light directing pipe, and a third light directing pipe. The first light directing pipe is connected to the light receiving module. The second light directing pipe is connected to the first light directing pipe. The third light directing pipe is connected to the second light directing pipe. All the light directing pipes are connected such that, after the installation of the system, the light receiving module can rotate horizontally or vertically around an axis to locate a preferable position. The light receiving module consists of a reflector assembly, which includes a primary reflector, a secondary reflector, and a downward exit pipe. The primary reflector has one or more reflecting units arranged in an arrayed structure with a concave surface to consense incident sunlight thereon, and direct it to the secondary reflector and then sequentially direct it through the first, second and third light directing pipes to a location where illumination is required.

Another feature of the present invention is that, the sunlight collecting system comprises a light receiving module, a first light directing pipe, a second light directing pipe, and a third light directing pipe. The first light directing pipe is connected to the light receiving module. The second light directing pipe is connected to the first light directing pipe. The third light directing pipe is connected to the second light directing pipe. All the light directing pipes are connected such that, after the installation of the system, the light receiving module can rotate horizontally or vertically around an axis to locate a preferable position. The light receiving module consists of multiple reflector assemblies, each of which includes a primary reflector, a second reflector, and a downward exit pipe. The primary reflector has one or more reflecting units arranged in an arrayed structure with a concave surface to condense incident sunlight thereon, and direct it to the secondary reflector and then sequentially direct it through the first, second and third light directing pipes to a location where illumination is required.

Another feature of the present invention is that, the sunlight collecting system comprises a light receiving module with a first light directing pipe, a second light directing pipe, and a third light directing pipe. The second light directing pipe is connected to the first light directing pipe of the light receiving module. The third light directing pipe is connected to the second light directing pipe. All the light directing pipes are connected such that, after the installation of the system, the light receiving module can rotate horizontally or vertically around an axis to locate a preferable position. The light receiving module includes a reflector assembly, which includes a primary reflector and a second reflector. The primary reflector has a concave surface to consense incident sunlight thereon, and direct it to the secondary reflector and then sequentially direct it through the first, second and third light directing pipes to a location where illumination is required.

Other objectives, advantages, and novel features of the present invention will become more apparent from the following detailed description when taken in conjunction with the accompanying drawings.

### BRIEF DESCRIPTION OF THE DRAWINGS

FIG. 1 is an exploded view of a first embodiment of the present invention.

FIG. 2 is a sectional view of the first embodiment of the present invention.

FIG. 3 is a schematic view showing angle adjustment of the orientation of the light receiving module of the first embodiment.

FIG. 4 is a partially enlarged 3-dimensional view showing a second embodiment of the present invention, in which multiple reflector assemblies are combined.

FIG. 5 is a partially enlarged sectional view showing the second embodiment of the present invention, in which multiple reflector assemblies are combined.

FIG. 6 is an exploded view showing the second embodiment of the present invention, in which multiple reflector assemblies are combined.

FIG. 7 is a sectional view schematically showing a third embodiment of the present invention.

FIG. 8 is an exploded view showing the third embodiment of the present invention.

FIG. 9 is a sectional view showing the third embodiment of the present invention.

FIG. 10 is a schematic view showing angle adjustment of the orientation of the light receiving module of the third embodiment.

### DETAILED DESCRIPTION OF THE PREFERRED EMBODIMENTS

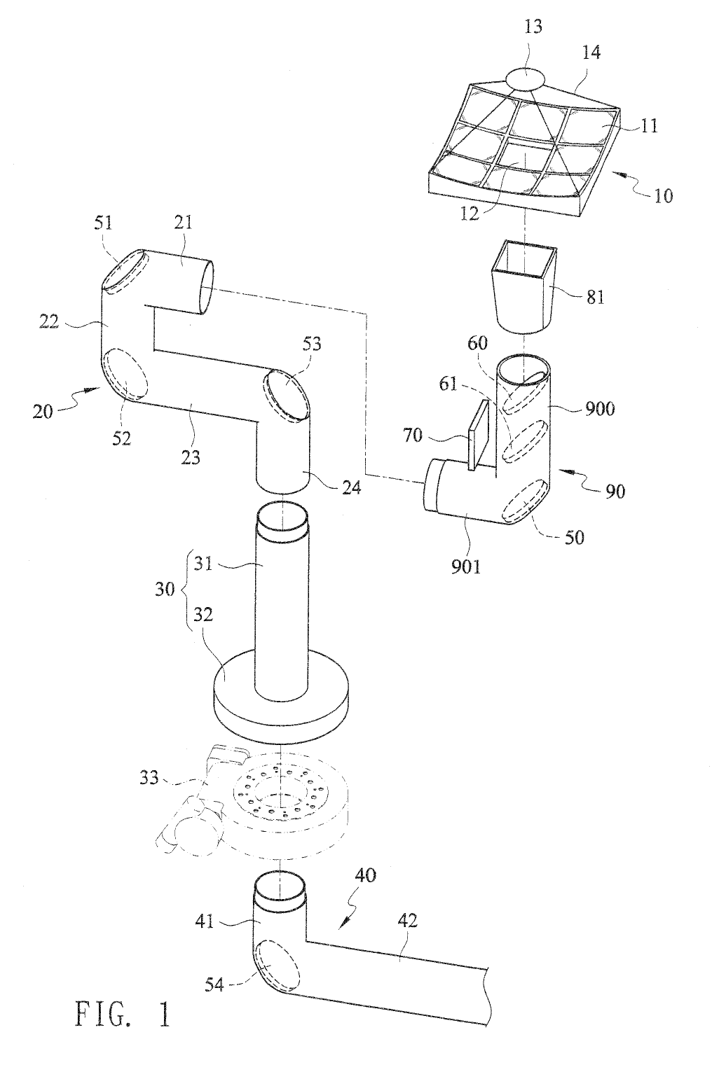

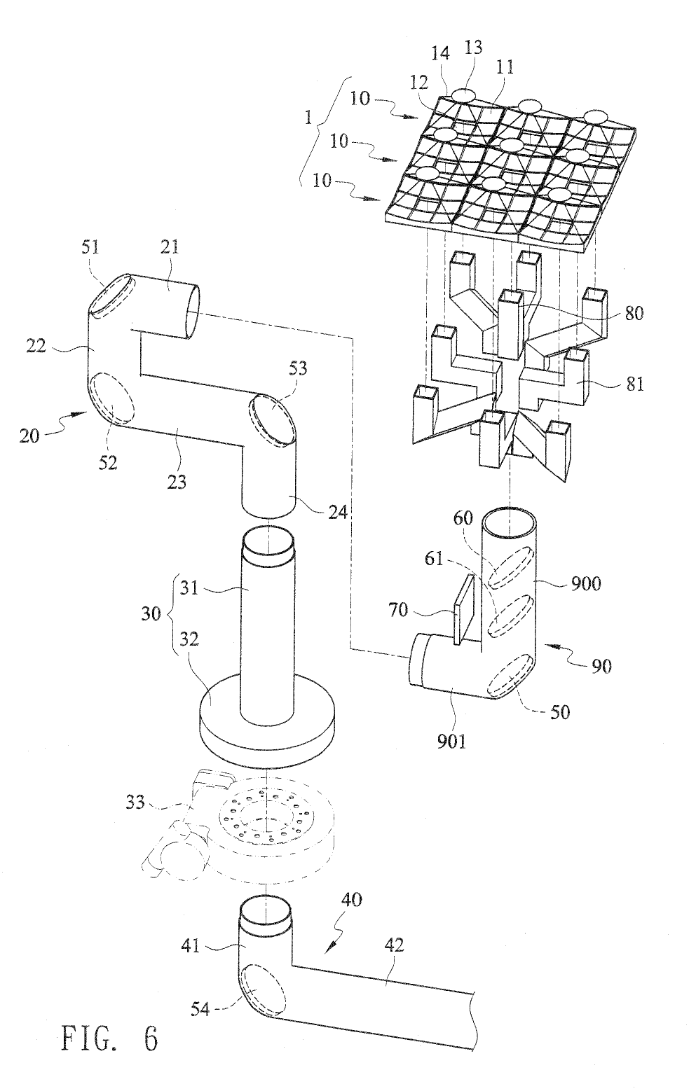

FIGS. 1 and 6 respectively show two embodiments of the present invention. As shown, the sunlight collecting system of the present invention generally comprises a light receiving module 1 for receiving incident sunlight, a first light directing pipe 90, a second light directing pipe 20, a swiveling means 30, and a third light directing pipe 40. The light receiving module 1 consists of one reflector assembly 10, which includes a primary reflector, a secondary reflector 13, and a downward exit pipe 81. The primary reflector is comprised of one or more reflecting units 11, being made of plastic film coated with reflective film, which are arranged in an arrayed structure having a predetermined area and a concave surface for condensing incident sunlight thereon. Furthermore, a through hole 12 is defined at a center of the arrayed structure surrounded by the reflecting units 11. A downward exit pipe 81 is located at rear of the arrayed structure in communication with the through hole 12. The secondary reflector 13 is mounted in front of the primary reflector at a predetermined distance from the primary reflector aligned with the through hole 12 via a supporting structure 14 of the reflector assembly or the arrayed structure for redirecting the condensed light from the primary reflector back into the through hole 12 and then through the downward exit pipe 81.

FIGS. 1, 2 and 3 show a first embodiment of the present invention with unitary primary reflector. As shown, the first light directing pipe 90 has an upward entry portion 900 for being connected with the downward exit pipe 81 of the reflector assembly 10 of the light receiving module 1 and a transverse exit portion 901 for being connected another pipe, wherein a bent portion of approximate 90 degrees is formed between the upward entry portion 900 and the transverse exit portion 901, and a reflector 50 is disposed in the bent portion.

A second light directing pipe 20 has a transverse entry portion 21, a middle upright portion 22, a middle transverse portion 23, and a downward exit portion 24, wherein three bent portions of approximate 90 degrees are respectively formed between the transverse entry portion 21 and the middle upright portion 22, between the middle upright portion 22 and the middle transverse portion 23, between the middle transverse portion 23 and the downward exit portion 24 of the second light directing pipe 20, three reflectors 51, 52, 53 are respectively disposed in the three bent portions. All the portions of the second light directing pipe 20 are approximately coplanar aligned. The transverse entry portion 21 of the second light directing pipe 20 is connected with the transverse exit portion 901 of the first light directing pipe 90.

A swiveling device 30 includes an upward entry pipe 31, a fixing flange 32 at one end of the upward entry pipe 31, and an actuating means 33 including a motor and a reduction gear (not shown). The upward entry pipe 31 is connected to the downward exit portion 24 of the second light directing pipe 20. The actuating means 33, which can be obtained from the existing products of the market and thus detailed description is eliminated, is connected between the fixing flange 32 and another pipe for swiveling the light receiving module 1 to a preferred location.

A third light directing pipe 40 has an upward entry portion 41, for being connected with the swiveling device 30 or the downward exit portion 24 of the second light directing pipe 20, and a transversely extending portion 42 for being connected to a location where illumination is required, wherein a bent portion of approximate 90 degrees is formed between the upward entry portion 41 and the transversely extending portion 42 of the third light directing pipe 40. Furthermore, the transversely extending portion 42 can be connected with another pipe with reflector according to a practical application for redirecting sunlight to a location where illumination is required, as the above described.

Furthermore, in a practical application, the third light directing pipe 40 can be connected with other light pipes, such as a pipe of fiber optics, to a location where illumination is required.

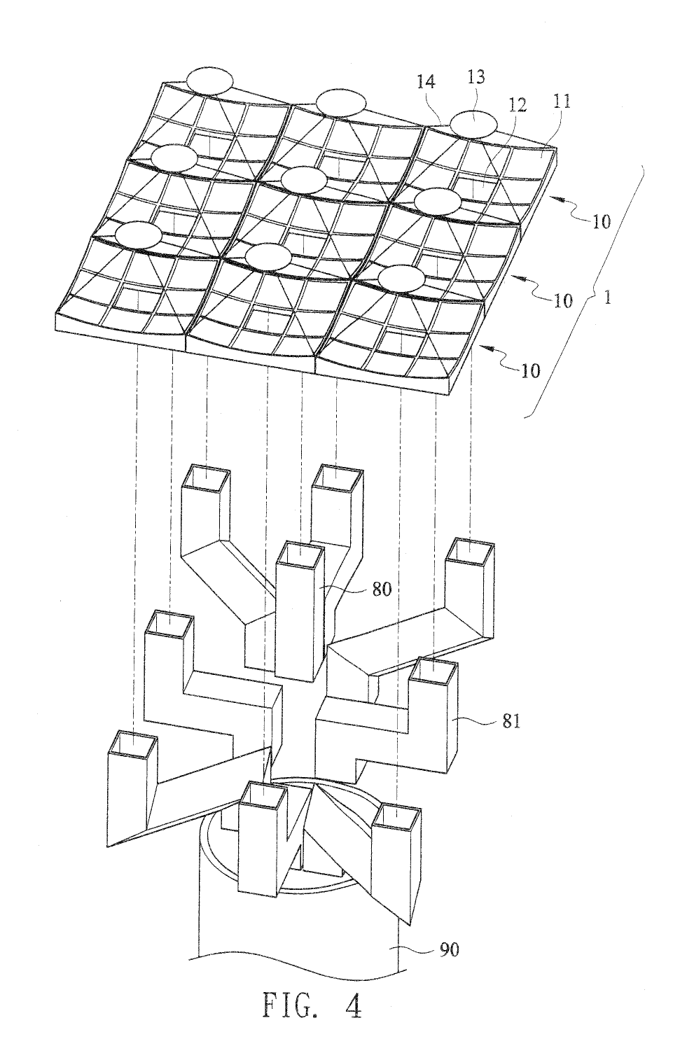

FIGS. 4, 5, and 6 show another embodiment of the present invention, in which multiple reflector assemblies 10 are assembled into a light receiving module 1 of a larger area. As shown, the reflector assemblies 10 are arranged in an array, in which each reflector assembly 10 is provided with a downward exit pipe 81 or 80 with or without reflectors therein. In this embodiment, there are nine reflector assemblies 10 and nine pieces of downward exit pipes 81, 80, in which sunlight L is directed to the first light directing pipe 90 via the downward exit pipes 81, 80, and then through the second light directing pipe 20, the swiveling device 30 and the third light directing pipe 40, and finally to a location where illumination is required so as to provide an environment for reading, decoration or ecology.

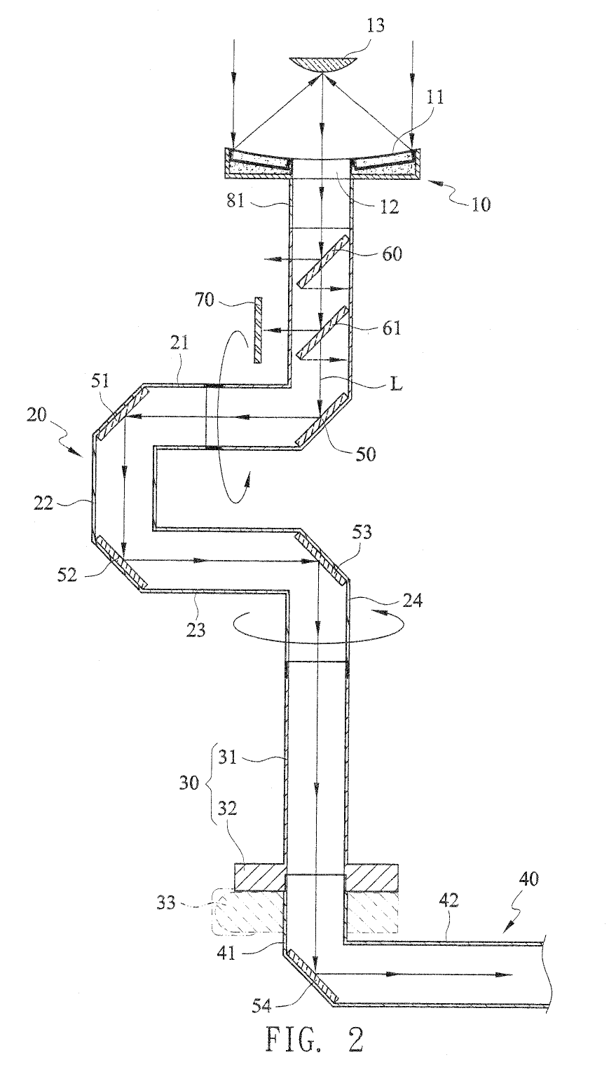

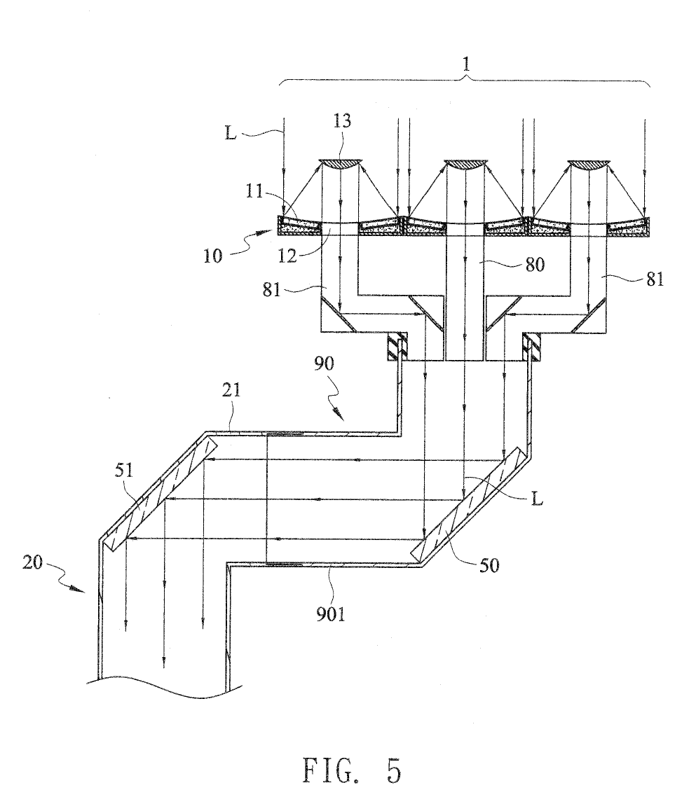

As shown in FIGS. 2 and 5, an ultraviolet light filter 60 or an infrared light filter 61 can be removably mounted in the upward portion 901 of the first light directing pipe 90, or the downward exit pipe 81 or 80 of the light receiving module 1 of the second embodiment (not shown). As both filters are a removable design, they can be removed when they are not required. Furthermore, the infrared light in the sunlight received from the light receiving module 1 can be redirected by the infrared light filter 61 to a location where photovoltaic cells are installed to have it absorbed and converted into electrical or heat energy for other uses before entering the first light directing pipe 90, such that the remaining light beam is suitable to be used for illumination in summer. On the contrary, when the present invention is used in winter, the infrared light filter 61 can be removed so as to increase the temperature within a room.

Alternatively, the ultraviolet filter 60 can also be mounted in the through hole 12 of the light receiving module 1 to filter the ultraviolet light in the sunlight.

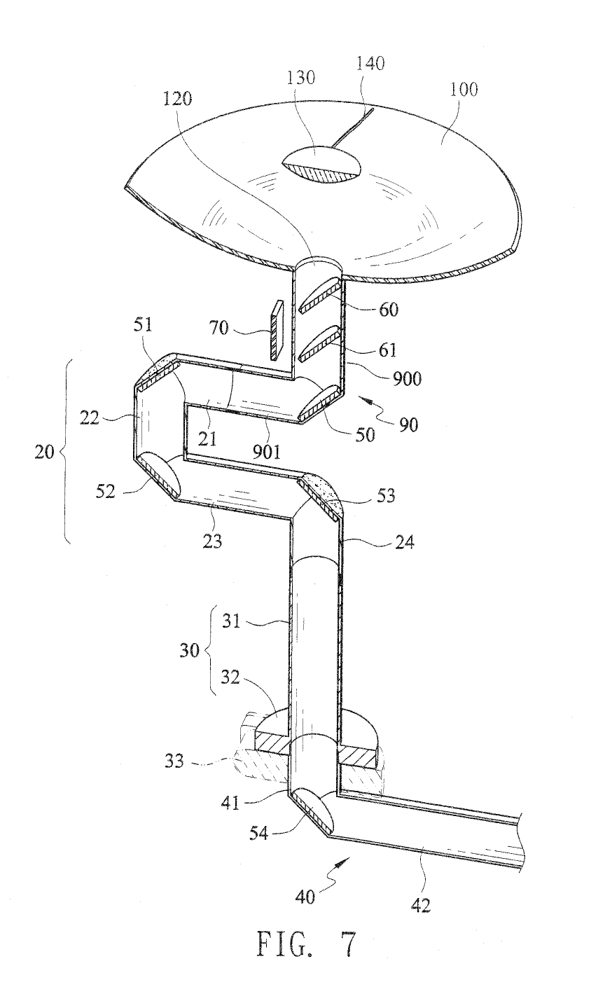

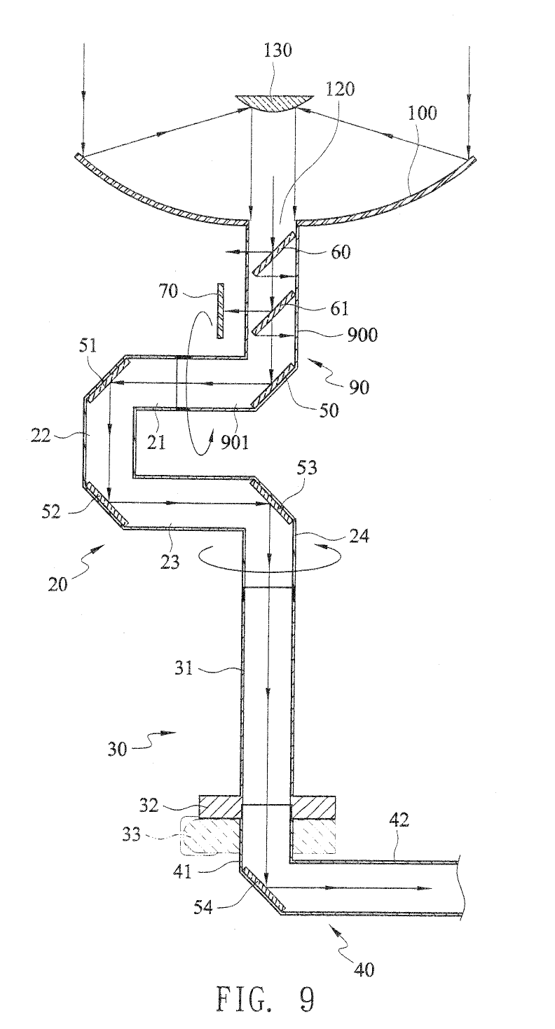

FIGS. 7, 8, 9, and 10 show a third embodiment of the present invention, in which the reflector assembly generally comprises a circular primary reflector 100, a secondary reflector 130, and a first light directing pipe 90 with a reflector 50 therein. The circular primary reflector 100 has a concave surface for condensing incident sunlight thereon. A through hole 120 is defined at a center of the reflector assembly 100. The first light directing pipe 90 is directly connected at rear of the reflector assembly 100 in communication with the through hole 120. The secondary reflector 130 is mounted in front of the circular primary reflector 100 at a predetermined distance from the circular reflector 100 aligned with the through hole 120 via a supporting structure 140 of the reflector assembly for redirecting the condensed light from the circular primary reflector 100 back into the through hole 120 and then through the first light directing pipe 90.

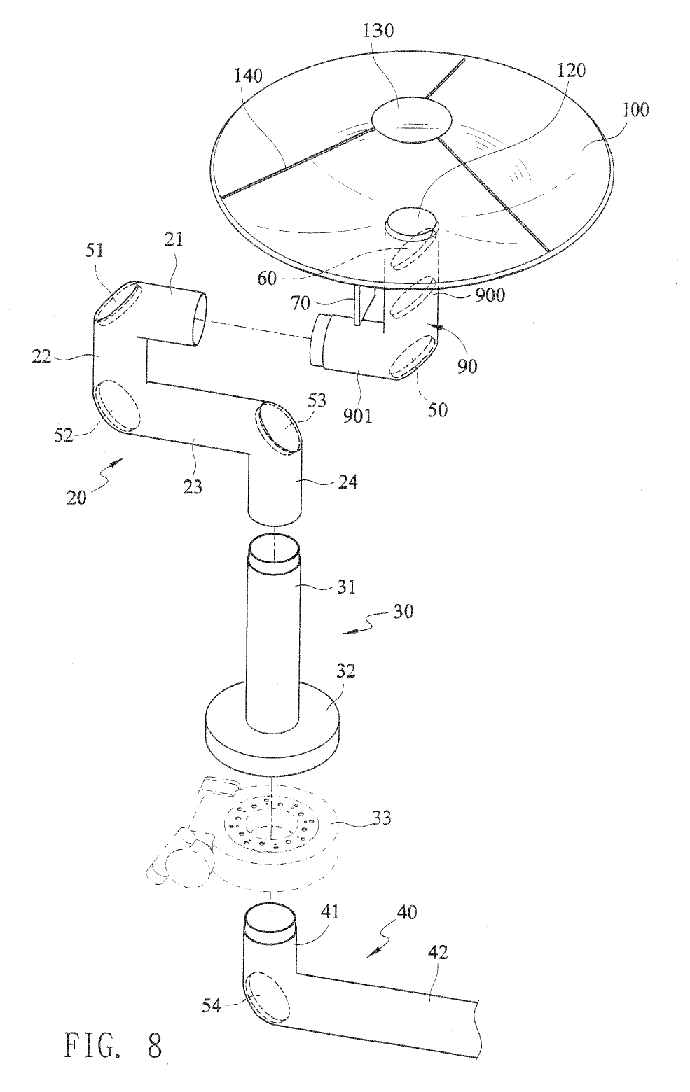

As shown in FIGS. 8, 9 and 10, the circular primary reflector 100, the secondary reflector 130, and the through hole 120 direct the sunlight into the second light directing pipe 20, the swiveling device 30, and the third light directing pipe 40 and finally to a location where illumination is required, in the same manner as the previous embodiments.

Preferably, all the above-mentioned pipes are each coated or attached with reflective film at their interior surfaces.

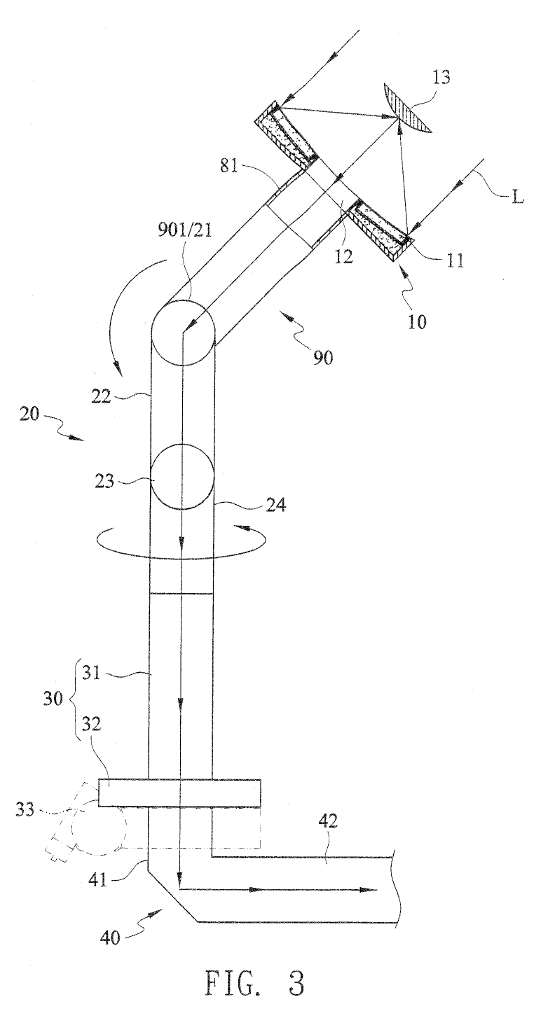

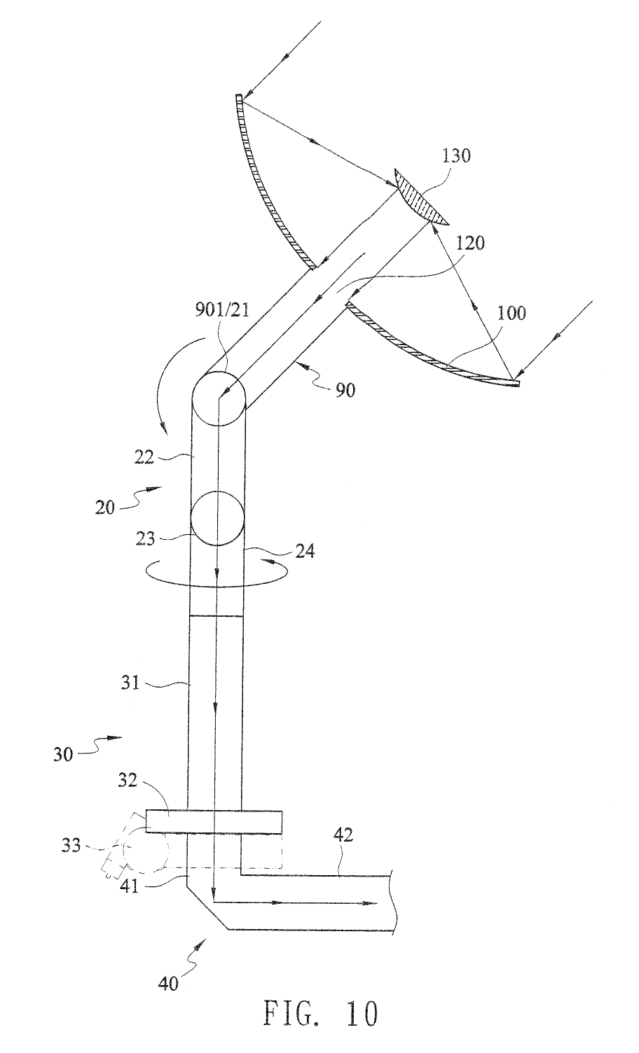

As shown in FIGS. 3 and 10, after the installation of the system, the light receiving module 1 can rotate horizontally or vertically around an axis to locate a preferable position, such that sunlight received by the primary reflector of the light receiving module can be directed to the secondary reflector of the light receiving module and then be redirected through the first light directing pipe 90, the second light directing pipe 20, the swiveling device 30, and the third light directing pipe 40 and finally to a location where illumination is required.

Although the present invention has been described with a certain degree of particularity, it is understood that the present disclosure is made by way of example only and the combination and arrangement of parts may be resorted to without departing from the spirit and scope of the invention hereinafter claimed.

I claim:

1. A sunlight collecting system comprising:
a light receiving module consisting of one reflector assembly, said reflector assembly including a primary reflector, a second reflector, and a downward exit pipe, said primary reflector having one or more reflecting units being made of plastic film coated with reflective film and arranged in an arrayed structure having a predetermined area and a concave surface for condensing incident sunlight thereon wherein a through hole is defined at a center of the arrayed structure surrounded by the reflecting units, said downward exit pipe located at rear of the arrayed structure in communication with said through hole, said secondary reflector mounted in front of said primary reflector at a predetermined distance from said primary reflector via a supporting structure of said reflector assembly aligned with said through hole for redirecting the condensed light from said primary reflector back into said through hole and then through said downward exit pipe;
a first light directing pipe, having an upward entry portion connected with said downward exit pipe of said light receiving module and a transverse exit portion, wherein a bent portion of approximate 90 degrees is formed between said upward entry poi lion and said transverse exit portion, and a reflector is disposed in said bent portion;
a second light directing pipe, having a transverse entry portion, a middle upright portion, a middle transverse portion and a downward exit portion, wherein three bent portions of approximate 90 degrees are respectively formed between said transverse entry portion and said middle upright portion, between said middle upright portion and said middle transverse portion, between said middle transverse portion and said downward exit portion of said second light directing pipe, three reflectors are respectively disposed in said three bent portions, all said portions of said second light directing pipe being approximately coplanar aligned, said transverse entry portion of said second light directing pipe being connected with said transverse exit portion of said first light directing pipe; and
a third light directing pipe, having an upward entry portion connected with said downward exit portion of said second light directing pipe and a transversely extending portion for being connected to a location where illumination is required, wherein a bent portion of approximate 90 degrees is formed between said upward entry portion and said transversely extending portion of said third light directing pipe;
wherein each reflector in said first, second and third light directing pipes are arranged to form a path for directing sunlight from said light receiving module; and
whereby, after the installation of the system, the light receiving module can rotate horizontally or vertically around an axis to locate a preferable position, such that sunlight received by said primary reflector can be directed to said secondary reflector and then sequentially directed through said first, second and third light directing pipes to a location where illumination is required.

2. The sunlight collecting system of claim 1, wherein an ultraviolet light filter is mounted in said upward entry portion of said first light directing pipe.

3. The sunlight collecting system of claim 1, wherein an infrared light filter is mounted in said upward entry portion of said first light directing pipe.

4. The sunlight collecting system of claim 3, wherein the infrared light in the sunlight received from said light receiving module is reflected by said infrared light filter and redirected to a location where photovoltaic cells are installed.

5. The sunlight collecting system of claim 1, wherein each said pipe is coated with a reflective film at its interior surface.

6. The sunlight collecting system of claim 1, further comprising a swiveling device mounted between said second light directing pipe and said third light directing pipe for swiveling said light receiving module, said swiveling device including a motor and a reduction gear.

7. A sunlight collecting system comprising:
a light receiving module consisting of a plurality of reflector assemblies, each reflector assembly includes a primary reflector, a secondary reflector, and a downward exit pipe, said primary reflector having one or more reflecting units being made of plastic film coated with reflective film and arranged in an arrayed structure having a predetermined area and a concave surface for condensing incident sunlight thereon wherein a through hole is defined at a center of the arrayed structure, said downward exit pipe located at rear of the arrayed structure in communication with said through hole, said secondary reflector mounted in front of said primary reflector at a predetermined distance from said primary reflector aligned with said through hole via a supporting structure of said reflector assembly for redirecting the condensed light from said primary reflector back into said through hole and then through said downward exit pipe;
a first light directing pipe, having an upward entry portion connected with said downward exit pipe of said light receiving module and a transverse exit portion, wherein a bent portion of approximate 90 degrees is formed between said upward entry portion and said transverse exit portion of said first light directing pipe, and a reflector is disposed in said bent portion;
a second light directing pipe, having a transverse entry portion, a middle upright portion, a middle transverse portion, and a downward exit portion, wherein three bent portions of approximate 90 degrees are respectively formed between said transverse entry portion and said middle upright portion, between said middle upright portion and said middle transverse portion, between said middle transverse portion and said downward exit portion of said second light directing pipe, three reflectors are respectively disposed in said three bent portions, all said portions of said second light directing pipe being approximately coplanar aligned, said transverse entry portion of said second light directing pipe being connected with said transverse exit portion of said first light directing pipe; and
a third light directing pipe, having an upward entry portion connected with said downward exit portion of said second light directing pipe and a transversely extending portion for being connected to a location where illumination is required, wherein a bent portion of approximate 90 degrees is formed between said upward entry portion and said transversely extending portion of said third light directing pipe;
wherein each reflector in said first, second and third light directing pipes are arranged to form a path for directing sunlight from said light receiving module; and
whereby, after the installation of the system, the light receiving module can rotate horizontally or vertically around an axis to locate a preferable position, such that sunlight received by said primary reflector can be directed to said secondary reflector and then sequentially directed through said first, second, and third light directing pipes to a location where illumination is required.

8. A sunlight collecting system comprising:
a light receiving module consisting of an reflector assembly, said reflector assembly including a primary reflector, a secondary reflector, and a first light directing pipe, said primary reflector have a concave surface for condensing incident sunlight thereon wherein a through hole is defined at a center of said primary reflector, said first light directing pipe being connected to a rear side of said primary reflector in communication with said through hole, said first light directing pipe having a bent portion of approximately 90 degrees in which a reflector is disposed and a transverse exit portion, said secondary reflector mounted in front of said primary reflector at a predetermined distance from said primary reflector aligned with said through hole via a supporting structure of said reflector assembly for redirecting the condensed light from said primary reflector back into said through hole and then through said first light directing pipe;
a second light directing pipe, having a transverse entry portion, a middle upright portion, a middle transverse portion, and a downward exit portion, wherein three bent portions of approximate 90 degrees are respectively formed between said transverse entry portion and said middle upright portion, between said middle upright portion and said middle transverse portion, between said middle transverse portion and said downward exit portion of said second light directing pipe, three reflectors are respectively disposed in said three bent portions, all said portions of said second light directing pipes being approximately coplanar aligned, said transverse entry portion of said second light directing pipe being connected with said transverse exit portion of said first light directing pipe; and
a third light directing pipe, having an upward entry portion connected with said downward exit portion of said second light directing pipe and a transversely extending portion for being connected to a location where illumination is required, wherein a bent portion of approximate 90 degrees is formed between said upward entry portion and said transversely extending portion of said third light directing pipe;
wherein each reflector in said first, second and third light directing pipes are arranged to form a path for directing sunlight from said light receiving module; and
whereby, after the installation of the system, the light receiving module can rotate horizontally or vertically around an axis to locate a preferable position, such that sunlight received by said primary reflector can be directed to said secondary reflector and then sequentially directed through said first, second, and third light directing pipes to a location where illumination is required.

9. The sunlight collecting system of claim 8, wherein each said pipe is coated with a reflective film at its interior surface.
